(19) United States
(12) Patent Application Publication
(10) Pub. No.: US 2026/0206956 A1
(43) Pub. Date: Jul. 23, 2026

(54) CLEANING BRUSH, SUBSTRATE CLEANING APPARATUS INCLUDING SAME, AND METHOD FOR MANUFACTURING SAME

(71) Applicant: SAMSUNG ELECTRONICS CO., LTD., Suwon-si (KR)

(72) Inventors: Gyunam KIM, Suwon-si (KR); Youngbin KIM, Suwon-si (KR); Bo-Gyeong KIM, Suwon-si (KR); Youngan SONG, Suwon-si (KR)

(73) Assignee: SAMSUNG ELECTRONICS CO., LTD., Suwon-si (KR)

(21) Appl. No.: 19/252,831

(22) Filed: Jun. 27, 2025

(30) Foreign Application Priority Data
Jan. 23, 2025 (KR) 10-2025-0010227

(51) Int. Cl. A46B 11/06; A46B 13/00; B08B 1/12; B08B 1/34; B08B 3/02

(52) U.S. Cl. CPC A46B 11/06; A46B 13/001; B08B 1/12; B08B 1/34; B08B 3/02

(57) ABSTRACT

A cleaning brush includes a core including an injection line extending in a first direction parallel to a central axis, a plurality of nodule-forming portions formed on an outer circumferential surface, and an inflow portion connecting the injection line and the plurality of nodule-forming portions in a radial direction intersecting the first direction, a plurality of nodules passing through the outer circumferential surface via the plurality of nodule-forming portions and is exposed to an exterior, and a filler connected to the plurality of nodules and including a first portion filled in the inflow portion and a second portion filled in at least part of the injection line.

### CROSS-REFERENCE TO RELATED APPLICATION

This application is based on and claims priority to Korean Patent Application No. 10-2025-0010227, filed in the Korean Intellectual Property Office on Jan. 23, 2025, the entire contents of which are hereby incorporated by reference.

### BACKGROUND

The disclosure relates to a cleaning brush, a substrate cleaning apparatus including the cleaning brush, and a method for manufacturing the cleaning brush.

In a semiconductor manufacturing process, an integrated circuit may generally be formed by depositing and etching a conductor, a semiconductor, and/or an insulator on a silicon wafer. During this process, a surface of the wafer becomes progressively rough, and a chemical mechanical polishing (CMP) process may be used to planarize the wafer.

However, after the chemical mechanical polishing process, impurities (particles), such as polishing byproducts and slurry, may remain on the surface of the wafer. Accordingly, a cleaning process to clean the wafer surface may be performed in order to remove such impurities (particles), including polishing byproducts and slurry.

The cleaning process may include cleaning using a cleaning brush, cleaning using ultrasound, and a process of drying the wafer. The cleaning process using a cleaning brush may refer to a process of brushing the wafer surface using at least one roll-type cleaning brush.

### SUMMARY

According to an aspect of the disclosure, there is provided a cleaning brush including: a core including: an injection line extending in a first direction parallel to a central axis, a plurality of nodule-forming portions formed on an outer circumferential surface of the core, and an inflow portion connecting the injection line and the plurality of nodule-forming portions in a radial direction intersecting the first direction; a plurality of nodules extending through the outer circumferential surface of the core via the plurality of nodule-forming portions; and a filler connected to the plurality of nodules, the filler including a first portion filled in the inflow portion and a second portion filled in at least part of the injection line.

According to an aspect of the disclosure, there is provided a substrate cleaning apparatus including: a cleaning liquid spray configured to supply a cleaning liquid onto a wafer; a cleaning brush configured to clean one surface of the wafer; a brush actuator configured to rotate the cleaning brush; and a cleaning liquid supply configured to supply the cleaning liquid to the cleaning brush, wherein the cleaning brush includes: a core including: a hollow portion formed in a first direction parallel to a central axis, an injection line extending in the first direction around the hollow portion, a plurality of nodule-forming portions formed on an outer circumferential surface of the core, and an inflow portion connecting the injection line and the plurality of nodule-forming portions in a radial direction intersecting the first direction; a plurality of nodules extending through the outer circumferential surface of the core via the plurality of nodule-forming portions; and a filler connected to the plurality of nodules and filled in the injection line and the inflow portion.

According to an aspect of the disclosure, there is provided a method of manufacturing a cleaning brush, including: forming a hollow portion in a core; forming a plurality of nodule-forming portions on an outer circumferential surface of the core; forming an injection line around the hollow portion; forming an inflow portion connecting the injection line and the plurality of nodule-forming portions; providing a mold having a plurality of cavities corresponding to the plurality of nodule-forming portions on the outer circumferential surface of the core; and injecting a filler material through the injection line.

According to some aspects the disclosure, when a substrate is cleaned using the cleaning brush according to an embodiment and the substrate cleaning apparatus including the same, the particles generated during cleaning may be reduced.

According to some aspects of the disclosure, by using the cleaning brush according to an embodiment, the substrate cleaning apparatus including the cleaning brush according to an embodiment, and the method for manufacturing the cleaning brush according to an embodiment, detachment of nodules from the cleaning brush may be prevented.

### BRIEF DESCRIPTION OF DRAWINGS

FIG. 1 illustrates a substrate cleaning apparatus according to some embodiments of the disclosure.

FIG. 2 is a perspective view illustrating a cleaning brush according to some embodiments of the disclosure.

FIG. 3 is a side view illustrating the cleaning brush according to some embodiments of the disclosure.

FIG. 4 is a cross-sectional view illustrating the cleaning brush according to some embodiments of the disclosure.

FIG. 5 is an enlarged view illustrating the cleaning brush according to some embodiments of the disclosure.

FIG. 6 is an enlarged view illustrating an enlarged portion of the cleaning brush according to some embodiments of the disclosure.

FIGS. 7 to 13 are diagrams illustrating a method of manufacturing the cleaning brush according to some embodiments of the disclosure.

### DETAILED DESCRIPTION

Hereinafter, with reference to the drawings, a cleaning brush according to some embodiments of the disclosure, a substrate cleaning apparatus including the cleaning brush, and a method for manufacturing the cleaning brush will be described in detail.

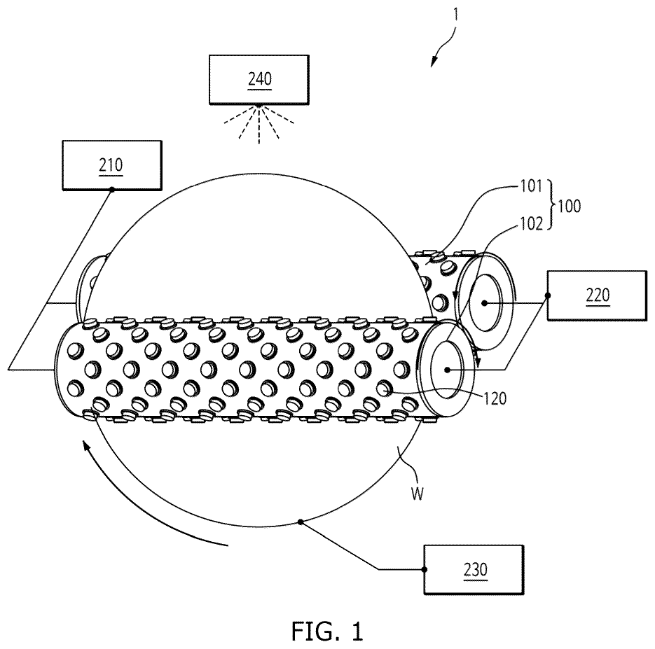

FIG. 1 illustrates a substrate cleaning apparatus according to some embodiments of the disclosure.

Referring to FIG. 1, in a semiconductor manufacturing process, after a polishing process (for example, a CMP process) has been performed on a wafer W, the wafer W may be cleaned by the substrate cleaning apparatus 1. According to an embodiment, the substrate cleaning apparatus 1 may include a cleaning brush 100, a cleaning liquid supply 210, a brush actuator 220, and a wafer actuator 230. In some embodiments, the substrate cleaning apparatus 1 may be referred to as a brush module.

The cleaning brush 100 may be provided on the wafer W to clean the wafer W. For example, the cleaning brush 100 may remove particles on the surface of wafer W. For example, the cleaning brush 100 may remove polishing residues on the surface of wafer W, but the disclosure is not limited to removing only the polishing residues. According to an embodiment, the cleaning brush 100 may include a plurality of cleaning brushes 101 and 102. For example, the cleaning brush 100 may include a first cleaning brush 101 provided on a first surface of wafer W and a second cleaning brush 102 provided on a second surface of the wafer W. However, the disclosure is not limited thereto, and as such, the number of cleaning brushes may be different than two. For example, the substrate cleaning apparatus 1 may include only one cleaning brush 100. For example, the substrate cleaning apparatus 1 may include only the first cleaning brush 101 provided on the first surface of the wafer W. In an example case in which the substrate cleaning apparatus 1 includes only the first cleaning brush, the first surface of wafer W may be a surface (for example, a front surface of wafer W) that has undergone the polishing process.

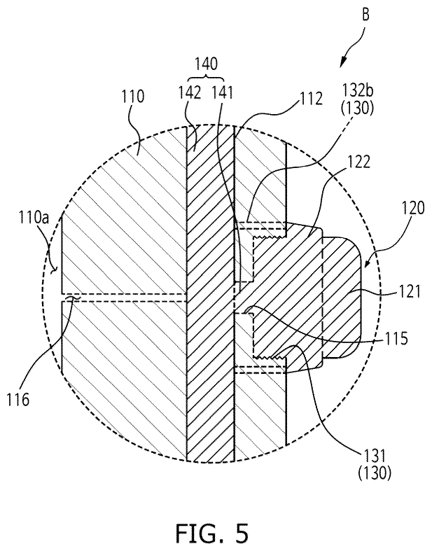

The cleaning liquid supply 210 may supply cleaning liquid to the cleaning brush 100. For example, the cleaning liquid supply 210 may be connected to one side of the cleaning brush 100. For example, the cleaning liquid may include deionized water (DI water) or the like. The cleaning liquid may infiltrate nodules 120 of cleaning brush 100. For example, the nodules 120 that have absorbed the cleaning liquid may clean wafer W more effectively. The process in which the cleaning liquid infiltrates nodules 120 is described below with reference to FIG. 5.

The brush actuator 220 may be connected to the cleaning brush 100. For example, the brush actuator 220 may be connected to one side of the central axis of the cleaning brush 100. The brush actuator 220 may be configured to rotate and/or move the cleaning brush 100. For example, the brush actuator 220 may include a drive motor configured to generate a driving force to rotate and/or move the cleaning brush 100. In an example case in which the cleaning brush 100 includes a plurality of the cleaning brushes 101 and 102, the brush actuator 220 may individually rotate and/or move each of the plurality of cleaning brushes 101 and 102.

According to an embodiment, the brush actuator 220 may rotate the cleaning brush 100 about a first rotation axis. For example, the first rotation axis may be located at the center of each of the cleaning brush 100. In an example case in which the cleaning brush 100 includes a plurality of the cleaning brushes 101 and 102, the brush actuator 220 may rotate each of the plurality of cleaning brushes 101 and 102 in the same direction or in different directions. In some embodiments, the brush actuator 220 may move the cleaning brush 100 so that the cleaning brush 100 approaches or moves away from the wafer W in order to adjust the contact degree between the cleaning brush 100 and the wafer W.

According to an embodiment, the wafer actuator 230 may be connected to the wafer W and may rotate and/or move the wafer W. For example, the wafer actuator 230 may rotate the wafer W about a second rotation axis (for example, the second rotation axis located at the center of the wafer W). For example, the wafer actuator 230 may include a drive motor configured to generate a driving force to rotate and/or move the wafer W. In an embodiment, the rotation axis (the first rotation axis) of the cleaning brush 100 and the rotation axis (the second rotation axis) of the wafer W may be perpendicular to each other.

According to an embodiment, the substrate cleaning apparatus 1 may further include a cleaning liquid spray 240 that includes a spraying nozzle. The cleaning liquid spray 240 may spray a cleaning liquid onto the wafer W. For example, the cleaning liquid may include, but is not limited to, deionized water (DI water), ammonia water (NH4OH), hydrofluoric acid (HF), or a mixed solution of at least some of these. As the cleaning liquid spray 240 sprays the cleaning liquid, cleaning of the wafer W may be performed more effectively. In an embodiment, the substrate cleaning apparatus 1 may further include a controller configured to control at least one of the cleaning liquid supply 210, the wafer actuator 230, or the cleaning liquid spray 240. For example, the controller may include a processor configured to execute one or more instructions stored in a memory. For example, the one or more instructions, when executed by the processor may cause the substrate cleaning apparatus 1 to perform one or more operations including, but not limited to, controlling at least one of the cleaning liquid supply 210, the wafer actuator 230, or the cleaning liquid spray 240.

Although FIG. 1 illustrates that the wafer W is provided in a direction perpendicular to the ground, the disclosure is not limited thereto, and as such, according to another embodiment, the wafer W may be provided in a direction parallel to the ground or at a certain angle relative to the ground.

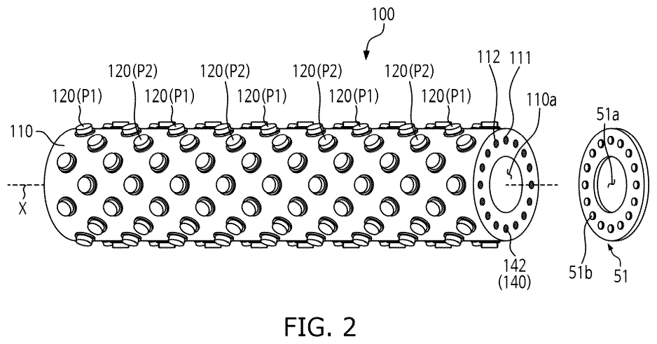

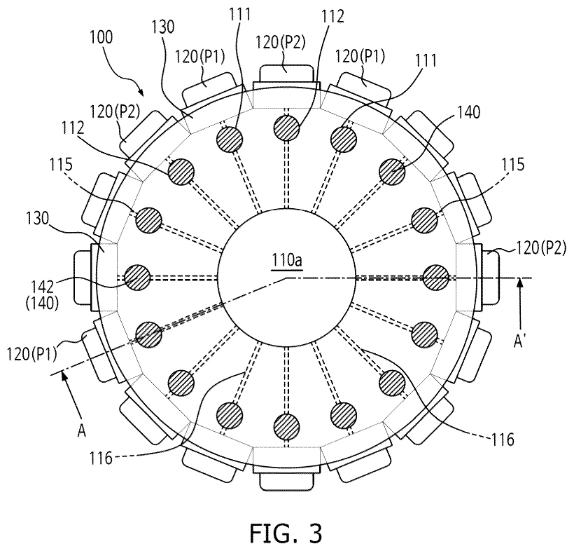

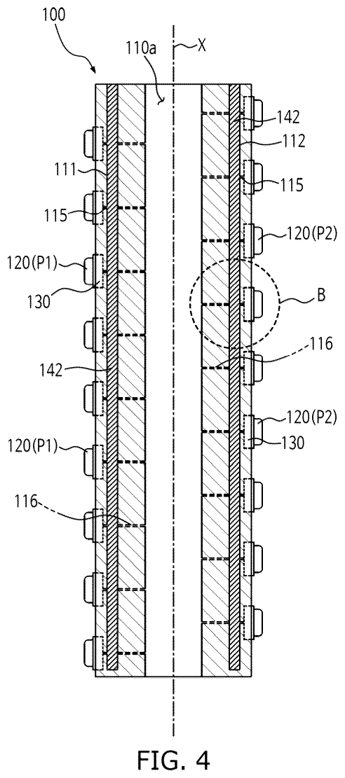

FIG. 2 is a perspective view illustrating the cleaning brush according to some embodiments of the disclosure. FIG. 3 is a side view illustrating the cleaning brush according to some embodiments of the disclosure. FIG. 4 is a cross-sectional view illustrating the cleaning brush taken along line A-A′ of FIG. 3 according to some embodiments of the disclosure.

Referring to FIGS. 2 to 4, the cleaning brush 100 according to some embodiments of the disclosure may include the core 110, a plurality of the nodules 120, and the filler 140.

The core 110 may be formed to extend in a first direction. For example, the first direction may be a direction of the central axis X. The core 110 may be formed in a cylindrical shape. For example, the core 110 may be a cylinder extending in the first direction. However, the shape of the core 110 is not limited thereto and may be a prism.

The core 110 may be configured to rotate about the central axis X extending in the first direction. Hereinafter, a radial direction may refer to a direction perpendicular to the central axis X, and a circumferential direction may refer to a direction of rotation around the central axis X. In other words, the core 110 may be a rotating body having the central axis X as a rotation axis. The central axis X may pass through the center of the core 110. The central axis X may extend along the longitudinal direction of the core 110. For example, the core 110 may rotate clockwise or counterclockwise about the central axis X. That is, the central axis X may be the rotation axis of the core 110. For example, the core 110 may be rotated by the brush actuator 220 (for example, as illustrated in FIG. 1).

The core 110 may include the hollow portion 110a, the injection lines 111 and 112, a plurality of the nodule-forming portions 130, an inflow portion 115, and a water supply portion 116.

According to an embodiment, the hollow portion 110a may pass through a region including the central axis X. In other words, the central axis X of the core 110 may pass through the hollow portion 110a. The hollow portion 110a may be defined as an empty space formed by passing through part of the core 110 that surrounds the central axis X. The hollow portion 110a may be cylindrical, extending in the first direction. For example, the hollow portion 110a may be cylindrical with a certain radius in the radial direction perpendicular to the central axis X.

According to an embodiment, the injection lines 111 and 112 may extend in the first direction. For example, the injection lines 111 and 112 may extend along the longitudinal direction of the core 110. The injection lines 111 and 112 may pass through part of the core 110 in the first direction. Each of the injection lines 111 and 112 may pass through one surface of the core 110 but may not necessarily pass through the opposite surface. For example, one end of each of the injection lines 111 and 112 may be open, and the other end of each of the injection lines 111 and 112 may be closed. In some embodiments, the injection lines 111 and 112 may pass through both surfaces of the core 110. The injection lines 111 and 112 may be formed around the hollow portion 110a. The injection lines 111 and 112 may radially correspond to the plurality of nodules 120, as will be described in detail below.

According to an embodiment, the injection lines 111 and 112 may include the first injection line 111 and the second injection line 112. The first injection line 111 and the second injection line 112 may be spaced apart at predetermined intervals along the circumferential direction. The first injection line 111 and the second injection line 112 may be alternately arranged along the circumferential direction. For example, the second injection line 112 may be provided between two adjacent the first injection lines 111, and the first injection line 111 may be provided between two adjacent second injection lines 112.

According to an embodiment, the plurality of nodule-forming portions 130 may be formed on the outer circumferential surface of the core 110. For example, each of the nodule-forming portions 130 may be formed by a portion of the outer circumferential surface of the core 110 that is recessed. The plurality of nodule-forming portions 130 may be arranged in the first direction. The plurality of nodule-forming portions 130 may be formed at locations where the plurality of nodules 120 will be formed. For example, the plurality of nodule-forming portions 130 may include first forming portions to form the first nodule pattern P1 and the second forming portions to form a second nodule pattern P2.

Each of the plurality of nodule-forming portions 130 may be connected the injection lines 111 and 112, so that the material injected through the injection lines 111 and 112 may move into the plurality of nodule-forming portions 130. The plurality of nodule-forming portions 130 may be formed by passing through a portion of the outer circumferential surface of the core 110. For example, a plurality of the nodule-forming portions 130 arranged along the first direction may be connected to each of the injection lines 111 and 112.

According to an embodiment, the inflow portion 115 may connect the injection lines 111 and 112 and the plurality of nodule-forming portions 130. The inflow portion 115 may be configured such that a material injected through the injection lines 111 and 112 may move into the plurality of nodule-forming portions 130 to form the plurality of nodules 120. For example, the material injected through the injection lines 111 and 112 may flow into the plurality of nodule-forming portions 130 through the inflow portion 115 and then be cured. The inflow portion 115 may extend in a radial direction intersecting the first direction. In other words, the inflow portion 115 may connect each of the injection lines 111 and 112 and the plurality of nodule-forming portions 130 in the radial direction.

According to an embodiment, the water supply portion 116 may connect the hollow portion 110a and the injection lines 111 and 112. The water supply portion 116 may be configured to supply the cleaning liquid to the plurality of nodules 120 and the filler 140. For example, the cleaning liquid may be injected into the hollow portion 110a to be supplied to the plurality of nodules 120 and the filler 140. For example, the cleaning liquid injected into the hollow portion 110a may permeate the filler 140 and the plurality of nodules 120 via the water supply portion 116 to the injection lines 111 and 112. The cleaning liquid may move to the nodules 120 by passing through the water supply portion 116, second portion 142 of the filler 140, and first portion 141 of the filler 140. The water supply portion 116 may extend in a radial direction intersecting the first direction. That is, the water supply portion 116 may connect each of the injection line 111 and the plurality of nodule forming portions 130 in the radial direction. In some embodiments, the filler 140 may fill at least part of the water supply portion 116. In other embodiments, the filler 140 may fill at least part of the hollow portion 110a.

According to an embodiment, a plurality of inflow portions 115 and a plurality of water supply portion 116 may be provided. The inflow portion 115 may connect each of the plurality of injection lines 111 to each of the plurality of nodule-forming portions 130. The water supply portion 116 may connect the hollow portion 110a and each of the plurality of injection lines 111.

According to an embodiment, the filler 140 may be filled inside the core 110. The filler 140 may be connected to the plurality of nodules 120. The filler 140 may be filled in at least part of the injection lines 111 and 112. In some embodiments, the filler 140 may be filled only in portions of the injection lines 111 and 112. The filler 140 may be formed by curing a material injected through the injection lines 111 and 112. The filler 140 may remain inside the injection lines 111 and 112 after the material for forming the plurality of nodules 120 has been injected.

According to an embodiment, the plurality of nodules 120 may be formed on the outer circumferential surface of the core 110. The plurality of nodules 120 may protrude from the outer circumferential surface of the core 110. The plurality of nodules 120 may pass through the outer circumferential surface of the core 110 and be exposed to the outside. According to embodiments of the disclosure, the cleaning brush 100 may be manufactured by injecting the filler into the core 110 to form a plurality of the nodules 120 protruding outward from the core 110. According to this example configuration of the cleaning brush 100 and the method manufacturing of the cleaning brush 100, the amount of the filler 140 used to form the plurality of nodules 120 may be reduced, and the generation of particles from the filler 140 may be reduced or prevented.

The plurality of nodules 120 may be formed of the same material as the filler 140. For example, each of the plurality of nodules 120 and the filler 140 may include, but is not limited to, a soft material (e.g., polyvinyl alcohol (PVA), polyurethane (PU), a porous material, etc.), a rigid material (e.g., silicon dioxide (SiO2)), a material having high thermal conductivity (e.g., polystyrene (PS), polyacrylamide (PAM), polyethylene (PE), polyphenylene oxide (PPO), polyvinylidene chloride (PVDC), or a material having higher thermal conductivity than at least one of these materials), or the like.

The plurality of nodules 120 may include, but is not limited to, the nodule patterns (P1 and P2) arranged in the first direction. In each of the nodule patterns (P1 and P2), the plurality of nodules 120 may be spaced at predetermined intervals along the first direction. While the cleaning brush 100 cleans the wafer, the plurality of nodules 120 may directly contact the wafer. For example, as the cleaning brush 100 rotates by the brush actuator 220 (see FIG. 1), the plurality of nodules may sequentially come into contact with the wafer.

The nodule patterns P1 and P2 may include the first nodule pattern P1 and the second nodule pattern P2. The first nodule pattern P1 and the second nodule pattern P2 may be spaced at predetermined intervals along the circumferential direction. The first nodule pattern P1 and the second nodule pattern P2 may be arranged alternately along the circumferential direction. For example, second nodule pattern P2 may be arranged between two adjacent the first nodule patterns P1, and the first nodule pattern P1 may be arranged between two adjacent second nodule patterns P2.

The first nodule pattern P1 and the second nodule pattern P2 may be arranged in a staggered manner. For example, each nodule of the first nodule pattern P1 and each nodule of the second nodule pattern P2 may be arranged so as not to overlap in the circumferential direction. However, the arrangement or number of the first nodule pattern P1 and the second nodule pattern P2 is not limited to this example and may be variously configured.

The first nodule pattern P1 may correspond to the first injection line 111, and the second nodule pattern P2 may correspond to second injection line 112. For example, the first injection line 111 may be arranged so as to radially correspond to the first nodule pattern P1, and the second injection line 112 may be arranged so as to radially correspond to second nodule pattern P2.

According to an embodiment, the cleaning brush 100 may be coupled with the end cap 51 as illustrated in FIG. 2. For example, the end cap 51 may be coupled to one end of the cleaning brush 100. In some embodiments, the end cap 51 may be coupled to both ends of the cleaning brush 100.

The end cap 51 may include the end cap hole 51a and the cap protrusion 51b. The end cap hole 51a may correspond to the hollow portion 110a of the core 110. Through the end cap hole 51a, the cleaning liquid or the like may be supplied into the hollow portion 110a.

The cap protrusion 51b may correspond to the injection lines 111 and 112 of the core 110. The cap protrusion 51b may prevent the cleaning liquid from flowing out through the filler 142 filled in the injection lines 111 and 112. A plurality of the cap protrusions 51b may be provided to correspond to the injection lines 111 and 112. Each of the cap protrusions 51b may be inserted into each of the injection line 111 and 112. The End cap 51 may be coupled to the cleaning brush 100 by inserting the cap protrusions 51b into the injection lines 111 and 112.

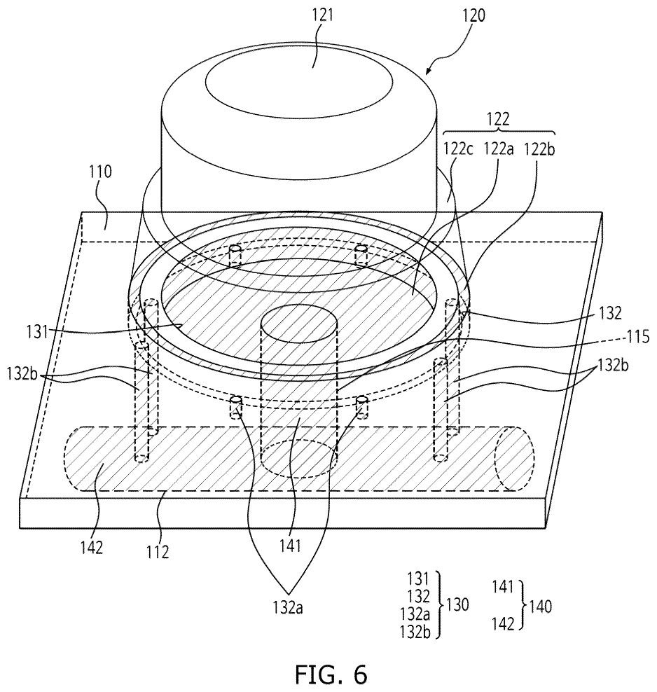

FIG. 5 is an enlarged view illustrating the cleaning brush according to some embodiments of the disclosure. FIG. 6 is an enlarged view illustrating a partial enlargement of the cleaning brush according to some embodiments of the disclosure. FIG. 5 may correspond to region B of FIG. 4.

Referring to FIGS. 5 and 6, the filler 140 may include a first portion 141 filled in the inflow portion 115 and a second portion 142 filled in at least part of the injection lines 111 and 112. The first portion 141 may be a portion connecting the plurality of nodules 120 and the second portion 142 within the injection lines 111 and 112. The second portion 142 may be an extended portion within the injection lines 111 and 112.

Each of the nodule-forming portions 130 may include the center groove 131 and the peripheral groove 132. The center groove 131 and the peripheral groove 132 may be formed by recessing a portion of the outer circumferential surface of the core 110. The center groove 131 and the peripheral groove 132 may define spaces for inserting portions of the nodules 120. The center groove 131 may have a shape corresponding to the cleaning portion 121, and the peripheral groove 132 may have a shape corresponding to the nodule base 122. For example, the cleaning portion 121 and the center groove 131 may overlap in the radial direction, and the nodule base 122 and the peripheral groove 132 may overlap in the radial direction. In some embodiments, each of the nodule-forming portions 130 may be formed as a single hole.

The center groove 131 may be formed by recessing a portion of the outer circumferential surface of the core 110. In a plan view of the outer circumferential surface of the core 110, the center groove 131 may be circular. However, the disclosure is not limited thereto, and as such, the center groove 131 may have a different shape. According to an embodiment, a thread may be formed on the circumferential surface of the center groove 131. The fixing force of the nodule 120, which is formed to contact the inner surface of the center groove 131, may be enhanced based on the thread formed on the circumferential surface of the center groove 131. In other words, detachment of the nodules 120 from the center groove 131 may be prevented.

The inflow portion 115 may be formed inside the center groove 131 so as to be connected to the injection line 112. The center groove 131 may connected to the injection line 112 through the inflow portion 115. The material injected through the injection line 112 may flow into the center groove 131 through the inflow portion 115. In an example case in which the material filled in the inflow portion 115 cures, that cured material may become first portion 141 of the filler 140. For example, when the material filled in the inflow portion 115 cures, that cured material may become first portion 141 of the filler 140. In this way, the nodule 120 formed therein may pass through the outer circumferential surface of the core 110 and be exposed to the outside. In some embodiments, a thread may be formed on the inner circumferential surface of the inflow portion 115.

The peripheral groove 132 may be formed outside the center groove 131. For example, the peripheral groove 132 may be formed at a position spaced outward from the center groove 131. In some embodiments, a thread may be formed on the inner side of the peripheral groove 132. A parts of the nodules 120 may be located in the center groove 131 and the peripheral groove 132. As an example, the part of the nodule base 122 may be inserted into the center groove 131 and the peripheral groove 132.

The peripheral groove 132 may have the fixing hole 132a and the communication hole 132b connected thereto.

The fixing hole 132a may be formed so as to connect to the bottom surface of the peripheral groove 132. The fixing hole 132a may be formed by recessing from the bottom surface of the peripheral groove 132. The fixing hole 132a may not overlap the injection line 112 in the radial direction relative to the central axis X of the core 110 (see FIG. 4). That is, even if the fixing hole 132a is formed deeper in the radial direction, it may not be in communication with the injection line 112.

According to an embodiment, a connection hole 132b may be formed to connect to the bottom surface of the peripheral groove 132. For example, the connection hole 132b may overlap the injection line 112 radially to connect with the injection line 112. Through connection hole 132b, the peripheral groove 132 and the injection line 112 may be connected with each other. For example, the connection hole 132b may overlap the injection line 112 radially relative to the central axis X of the core 110 (see FIG. 4).

According to an embodiment, a plurality of the fixing holes 132a and the communication holes 132b may be formed. The fixing holes 132a and the communication holes 132b may be spaced apart at different positions along the peripheral groove 132. The plurality of fixing holes 132a may be formed at positions spaced apart along the extension direction of the injection line 112. The plurality of communication holes 132b may be formed at positions spaced apart along the extension direction of the injection line 112.

Each of the plurality of nodules 120 may include the cleaning portion 121 and the nodule base 122.

The cleaning portion 121 may contact the wafer W in order to clean the wafer W. The cleaning portion 121 may deform while being rubbed against the wafer W. For example, friction between the cleaning portion 121 and the wafer W may cause the cleaning portion 121 to bend in a direction opposite to the rotation of the cleaning brush 100. In order to reduce or prevent detachment or damage of the cleaning portion 121 due to such deformation, the nodule base 122 may be provided. In other words, the cleaning portion 121 may be formed integrally with the nodule base 122 and may protrude from the nodule base 122. In some embodiments, an end of the cleaning portion 121 may be rounded.

The nodule base 122 may be configured such that its cross-sectional area decreases as the distance from the central axis increases. The nodule base 122 may be configured such that its cross-sectional area decreases as it extends further outward from the outer circumferential surface of the core 110. The nodule base 122 may prevent stress from concentrating on the portion where the cleaning portion 121 is fixed, which may occur during the wafer cleaning. In other words, by means of the nodule base 122, the angle at which the cleaning portion 121 is connected may be made more gradual.

The nodule base 122 may include the center insertion part 122a, the peripheral insertion part 122b, and the inclined part 122c.

The center insertion part 122a may be inserted into the center groove 131, and the peripheral insertion part 122b may be inserted into the peripheral groove 132. A portion of the core 110 may be located between the center insertion part 122a and the peripheral insertion part 122b.

The inclined part 122c may be formed so that its cross-sectional area decreases as it extends farther away from the core 110. For example, the side surface of the inclined part 122c may be inclined in a direction in which its width decreases as it becomes more distant from the center insertion part 122a and the peripheral insertion part 122b. The Inclined part 122c may be located above the center insertion part 122a and the peripheral insertion part 122b. The cleaning portion 121 may be located on the inclined part 122c. In some embodiments, part of the side surface of the inclined part 122c may be rounded.

In this manner, part of each of the nodules 120 is inserted into the center groove 131 and the peripheral groove 132, thereby reducing or preventing detachment of the nodule 120.

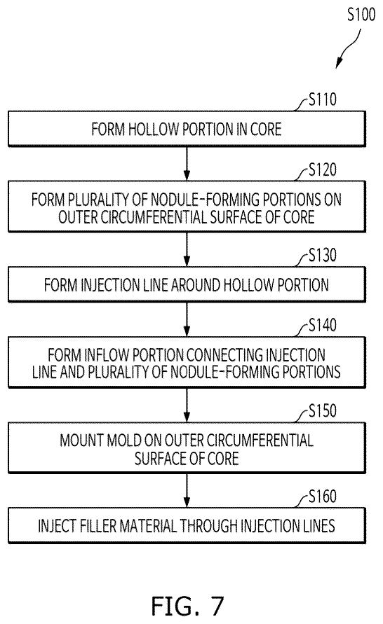

FIGS. 7 to 13 are diagrams illustrating the method of manufacturing the cleaning brush according to some embodiments of the disclosure. Hereinafter, the method S100 of manufacturing the cleaning brush according to some embodiments of the disclosure will be described.

In the method of some embodiments described below, certain operations may be performed in an order different from that described if otherwise implementable. For example, two operations described in succession may be performed substantially simultaneously, or may be performed in the reverse order from that described.

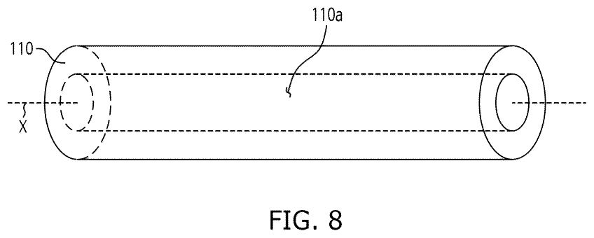

Referring to FIGS. 7 and 8, the method S100 of manufacturing the cleaning brush according to some embodiments of the disclosure may include an operation S110 of forming the hollow portion in the core.

According to an embodiment, operation S110 may include preparing a preliminary core. The preliminary core may be cylindrical in shape, and extending in a first direction. The preliminary core may be a rotating body around the central axis X.

According to an embodiment, a part of the preliminary core may be removed. For example, a region including the central axis X of the preliminary core may be removed. A region extending in the direction that includes the central axis X of the preliminary core may be removed. The removed region may be cylindrical, sharing the central axis X and having a certain length in the radial direction. In this way, the core 110 having the hollow portion 110a formed therein may be manufactured. In some embodiments, the operation S110 of forming the hollow portion may be omitted or may be carried out before an operation S150 of mounting the mold on the outer circumferential surface of the core.

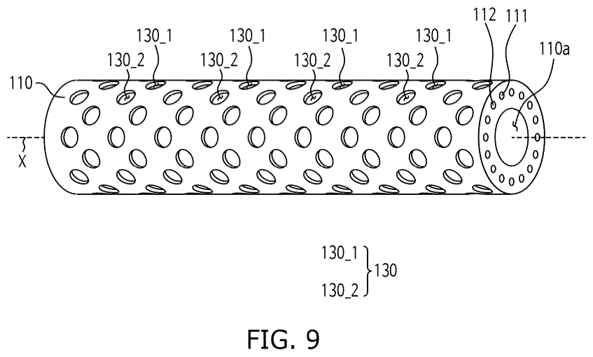

Referring to FIGS. 7 and 9, the method S100 of manufacturing the cleaning brush according to some embodiments of the disclosure may include an operation S120 of forming a plurality of the nodule-forming portions on the outer circumferential surface of the core. The plurality of nodule-forming portions 130 may be in the form illustrated in FIGS. 5 and 6, but the disclosure is not limited thereto.

The plurality of nodule-forming portions 130 on the outer circumferential surface of the core 110 may include first forming portions 130_1 for forming the first nodule pattern and the second forming portions 130_2 for forming a second nodule pattern. Each of first forming portions 130_1 and the second forming portions 130_2 may be formed at positions where the first and the second nodule patterns are to be formed.

Each of first forming portions 130_1 and the second forming portions 130_2 may be arranged at predetermined intervals in the first direction. For example, the first forming portions 130_1 may be arranged with a first interval between adjacent first forming portions 130_1 and the second forming portions 130_2 may be arranged with a second interval between adjacent second forming portions 130_1. According to an embodiment, the first interval and the second interval may be different from each other. However, the disclosure is not limited thereto, and as such, the first interval and the second interval may be same. Each of first forming portions 130_1 and the second forming portions 130_2 may be located at positions spaced apart along the circumferential direction. First forming portions 130_1 and the second forming portions 130_2 may be arranged in a staggered manner. Each forming portion of first forming portions 130_1 and each forming portion of second forming portions 130_2 may be formed so as not to overlap in the circumferential direction of the core 110.

The method S100 of manufacturing the cleaning brush according to some embodiments of the disclosure may include an operation S130 of forming the injection line around the hollow portion.

The injection lines 111 and 112 may be formed around the hollow portion 110a. The injection lines 111 and 112 may extend in a first direction. The injection lines 111 and 112 may pass in the first direction through part of the core 110. Each of the injection lines 111 and 112 may pass through one surface of the core 110 but may not pass through the opposite surface. That is, the injection lines 111 and 112 may be formed by passing from one surface toward the other surface of the core 110 in the longitudinal direction, without necessarily penetrating the other surface. In other words, the injection lines 111 and 112 may be formed so as to extend only part of the way through the length of the core 110. The injection lines 111 and 112 may extend parallel to the central axis X. The injection lines 111 and 112 may each be approximately cylindrical. The diameter of the injection lines 111 and 112 may be smaller than that of the hollow portion 110a.

The injection lines 111 and 112 may be spaced apart at predetermined intervals along the circumferential direction around the hollow portion 110a. The injection lines 111 and 112 may be spaced apart at uniform intervals. The injection lines 111 and 112 may be arranged so as to surround the hollow portion 110a.

The injection lines 111 and 112 may be formed at positions corresponding to first forming portions 130_1 and the second forming portions 130_2 of the core 110. The first injection line 111 and the second injection line 112 may each be formed at positions corresponding to first forming portions 130_1 and the second forming portions 130_2, respectively. For example, the first forming portions 130_1 may overlap the first injection line 111 in the radial direction of the core 110, and the second forming portions 130_2 may overlap second injection line 112 in the radial direction of the core 110.

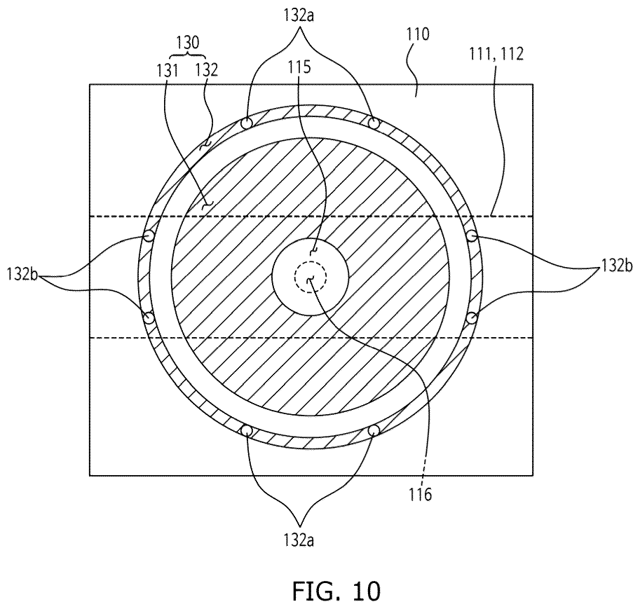

Referring to FIG. 10, the operation S130 of forming a plurality of the nodule-forming portions on the outer circumferential surface of the core may include an operation of forming a center groove and a peripheral groove.

According to an embodiment, a center groove 131 may be formed by tap processing. By tap processing, a thread may be formed on the circumferential surface of the center groove 131. The center groove 131 may be circular with a predetermined diameter. However, the shape of the center groove 131 is not limited thereto and may be variously implemented.

According to an embodiment, a peripheral groove 132 may be formed around the center groove 131. For example, the peripheral groove 132 may be formed at a position spaced apart from the center groove 131. The peripheral groove 132 may be ring-shaped with a predetermined diameter. In some embodiments, the peripheral groove 132 may be formed by tap processing so that a thread is formed on its circumferential surface.

According to an embodiment, the operation S130 of forming the plurality of nodule-forming portions on the outer circumferential surface of the core may include the forming the fixing hole in the ferrule groove, and forming the connection hole in the ferrule groove so as to from a channel to connect with the injection line.

According to an embodiment, a fixing hole 132a may be formed in part of peripheral groove 132 (for example, part of the bottom surface). The fixing hole 132a may have a predetermined depth. According to an embodiment, a plurality of fixing holes 132a may be formed. For example, the plurality of fixing holes 132a may be formed in two pairs facing each other around the center groove 131. The plurality of fixing holes 132a may be spaced apart in a direction perpendicular to the extension direction of the injection lines 111 and 112. The depth of the plurality of fixing hole 132a may be smaller than that of the connection hole 132b.

According to an embodiment, the connection hole 132b may be formed in part of the peripheral groove 132 (for example, part of the bottom surface). The connection hole 132b may have a predetermined depth. The connection hole 132b may overlap the injection lines 111 and 112 in the radial direction to form a channel to connect with the injection lines 111 and 112. That is, the material injected into the injection lines 111 and 112 may flow out through the connection hole 132b.

According to an embodiment, a plurality of connection holes 132b may be formed. For example, the plurality of connection holes 132b may be formed in two pairs facing each other. The plurality of connection holes 132b may be spaced apart in a direction parallel to the extension direction of the injection lines 111 and 112.

Referring to FIGS. 7 and 10, the method S100 of manufacturing the cleaning brush according to some embodiments of the disclosure may include an operation S140 of forming an inflow portion connecting the injection line and the plurality of nodule-forming portions.

For example, the inflow portion 115 may be formed in the center groove 131. The diameter of the inflow portion 115 may be smaller than that of the center groove 131. The inflow portion 115 may be arranged to connect the center of the center groove 131. The inflow portion 115 may provide a channel or a conduit between the injection lines 111 and 112 and the center groove 131. In this manner, when the material for the filler is injected through the injection lines, the material may fill the center groove 131 through the inflow portion 115 and then cure to form the filler.

The method S100 of manufacturing the cleaning brush according to some embodiments of the disclosure may further include forming the water supply portion connecting the injection line and the hollow portion.

After the inflow portion 115 is formed to connect with the inside of the center groove 131, the water supply portion 116 may be formed by passing through part of the core 110 via the injection lines 111 and 112. The water supply portion 116 may connect the injection lines 111 and 112 and the inflow portion 115. The diameter of the water supply portion 116 may be smaller than that of the inflow portion 115. The water supply portion 116 may extend in the same direction as the inflow portion 115. For example, the inflow portion 115 and the water supply portion 116 may extend in the radial direction of the core 110.

In some embodiments, when the material for the filler is injected through the injection lines 111 and 112, part of the filler material may flow into the water supply portion 116. Alternatively, part of the filler material may fill the water supply portion 116 completely and then flow into part of the hollow portion. That is, after curing, the formed the filler may exist in the hollow portion, the water supply portion 116, the injection lines 111 and 112, and the inflow portion 115.

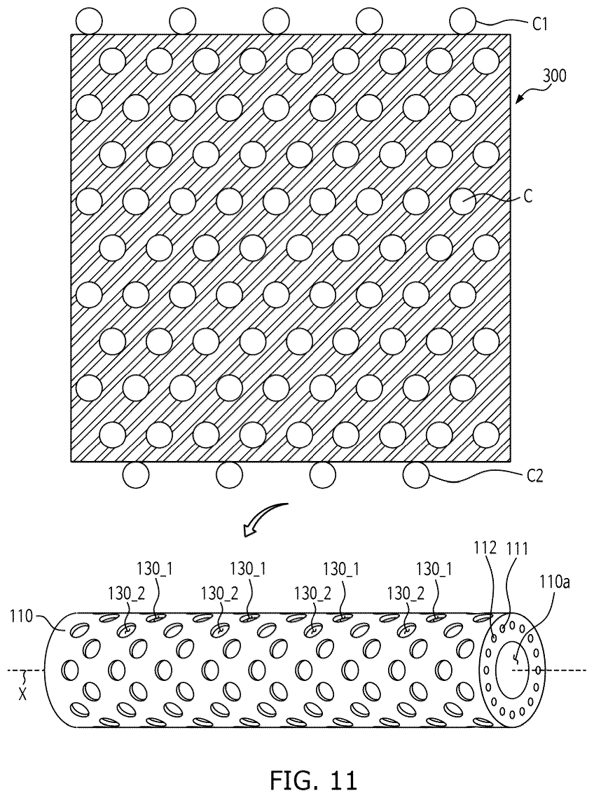

Referring to FIGS. FIGS. 7 and 11, the method S100 of manufacturing the cleaning brush according to some embodiments of the disclosure may include an operation S150 of mounting, on the outer circumferential surface of the core, the mold having a plurality of cavities corresponding to the plurality of nodule-forming portions.

The formwork 300 may have a plurality of cavities C. The cavities may have a shape corresponding to the shape of the nodules. For example, the cavities may have a shape corresponding to the cleaning portion and the nodule base of the nodule.

The plurality of cavities C may be formed so as to correspond to positions where the plurality of nodules are to be formed in an example case in which the mold 300 is coupled so as to surround the outer circumferential surface of the core 110. For example, the plurality of cavities C may be arranged in a staggered manner so as to correspond to the first and the second nodule patterns.

In some embodiments, the mold 300 may be a rectangular sheet. The mold 300 may include a flexible material. The Mold 300 may wrap around the outer circumferential surface of the core 110. In some embodiments, the mold 300 may include a rigid material having a certain shape. In this embodiment, the mold 300 may be detachably coupled to the core 110.

Mold 300 may have end cavities C1 and C2 provided at both ends. End cavities C1 and C2 may include first end the cavity C1 provided at one end of the mold 300, and the second end the cavity C2 provided at the other end of the mold 300. For example, the first end the cavity C1 and the second end the cavity C2 may be arranged in a staggered manner. In an example case in which the mold 300 is wrapped around the outer circumferential surface of the core 110, first end the cavity C1 and the second end the cavity C2 may be aligned along the first direction. In this manner, first end the cavity C1 and the second end the cavity C2 may be arranged to form a plurality of the nodules arranged in the first direction. In some embodiments, additional taping may be applied with the mold 300 mounted on the outer circumferential surface of the core 110. By taping, the mold 300 may be mounted more firmly on the outer circumferential surface of the core 110.

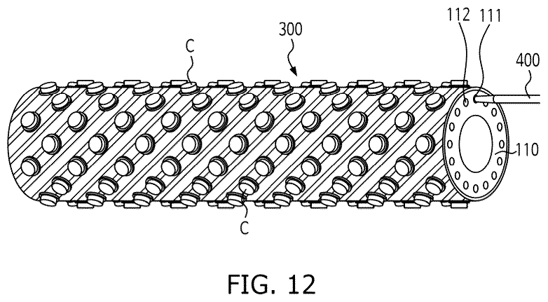

Referring to FIGS. 7 and 12, the method S100 of manufacturing the cleaning brush according to some embodiments of the disclosure may include an operation S160 of injecting the filler material through the injection lines.

According to an embodiment, the filler material may be injected into each of the injection lines 111 and 112 via the filler nozzle 400. With the mold 300 mounted on the outer circumferential surface of the core 110, the filler material may be injected through one side of each of the injection lines 111 and 112 via the filler nozzle 400. In an embodiment where the injection lines 111 and 112 pass through both surfaces of the core 110, the other side of the injection lines 111 and 112 may be covered by a cover member or the like to prevent outflow of the filler material. For example, the filler material may include a soft material (e.g., polyvinyl alcohol (PVA), polyurethane (PU), a porous material, etc.). In some embodiments, a plurality of the filler nozzles 400 may be provided so that the material can be injected into the plurality of injection lines 111 and 112 simultaneously.

The material injected into the injection lines 111 and 112 may flow into the space surrounded by the cavities C of the mold 300 and the nodule-forming portions via the inflow portion 115. After being filled in cavities C and the nodule-forming portions, the material may cure to form the nodules. The material may remain filled in the injection lines, the center groove, and the peripheral groove and then cure. As a result, the cured material may fill the center groove, fixing groove, and the peripheral groove including the plurality of connection holes.

Among the filler material injected, the portion filled in the nodule-forming portions may become the nodules 120. Among the injected the filler, the portion filled in the inflow portion may become first portion 141 (see FIG. 5), and the portion filled in the injection lines 111 and 112 may become second portion 142.

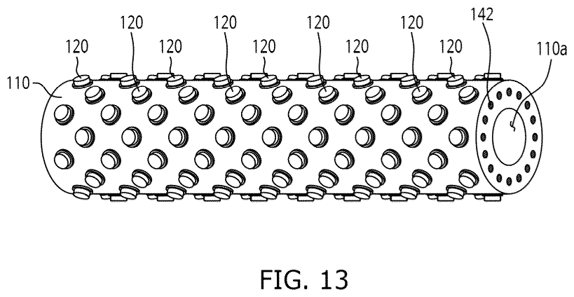

Referring to FIGS. 7 and 13, the method S100 of manufacturing the cleaning brush according to some embodiments of the disclosure may further include an operation of removing the mold.

The mold removal operation may be performed after the operation S160 of injecting the filler material through the injection lines. After sufficiently injecting the filler material through the injection lines and allowing the material to cure to form the plurality of nodules 120 and first and the second portions 142 of the filler, the mold may be removed.

While the present disclosure has been described above with reference to certain embodiments and drawings, the disclosure is not limited thereto, and it will be apparent to those of ordinary skill in the art to which the disclosure pertains that various modifications and variations are possible within the spirit and scope of the disclosure and within the range of equivalents of the appended claims.

What is claimed is:

1. A cleaning brush comprising:
a core comprising:
an injection line extending in a first direction parallel to a central axis,
a plurality of nodule-forming portions formed on an outer circumferential surface of the core, and
an inflow portion connecting the injection line and the plurality of nodule-forming portions in a radial direction intersecting the first direction;
a plurality of nodules extending through the outer circumferential surface of the core via the plurality of nodule-forming portions; and
a filler connected to the plurality of nodules, the filler comprising a first portion filled in the inflow portion and a second portion filled in at least part of the injection line.

2. The cleaning brush according to claim 1, wherein each of the plurality of nodules comprises:
a nodule base having a cross-sectional area decreases as a distance from the central axis increases; and
a cleaning portion protruding from the nodule base.

3. The cleaning brush according to claim 2, wherein each of the plurality of nodule-forming portions comprises:
a center groove corresponding to the cleaning portion; and
a peripheral groove corresponding to the nodule base and spaced apart from the center groove,
wherein the inflow portion is connected to the center groove.

4. The cleaning brush according to claim 3, further comprising:
a thread is formed on a circumferential surface of the center groove.

5. The cleaning brush according to claim 3, wherein each of the plurality of nodule-forming portions further comprises:
a fixing hole in the peripheral groove; and
a connection hole in the peripheral groove, the connection hole overlapping the injection line in the radial direction.

6. The cleaning brush according to claim 1, wherein the core further comprises:
a hollow portion, wherein the central axis passes through the hollow portion, and wherein the injection line is spaced in the radial direction from the hollow portion.

7. The cleaning brush according to claim 6, wherein the plurality of nodules form a nodule pattern arranged in the first direction, and wherein the injection line is provided to correspond with the nodule pattern in the radial direction.

8. The cleaning brush according to claim 7, wherein the core further comprises a water supply portion provided between the injection line and the hollow portion in the radial direction.

9. The cleaning brush according to claim 7, wherein the nodule pattern comprises:
a first nodule pattern arranged in the first direction; and
a second nodule pattern arranged in the first direction and spaced from the first nodule pattern by a first interval in a circumferential direction of the core,
wherein the injection line comprises:
a first injection line provided in the radial direction to correspond to the first nodule pattern; and
a second injection line provided in the radial direction to correspond to the second nodule pattern.

10. The cleaning brush according to claim 1, wherein the plurality of nodules and the filler each comprise a same material.

11. A substrate cleaning apparatus comprising:
a cleaning liquid spray configured to supply a cleaning liquid onto a wafer;
a cleaning brush configured to clean one surface of the wafer;
a brush actuator configured to rotate the cleaning brush; and
a cleaning liquid supply configured to supply the cleaning liquid to the cleaning brush,
wherein the cleaning brush comprises:
a core comprising:
a hollow portion formed in a first direction parallel to a central axis,
an injection line extending in the first direction around the hollow portion,
a plurality of nodule-forming portions formed on an outer circumferential surface of the core, and
an inflow portion connecting the injection line and the plurality of nodule-forming portions in a radial direction intersecting the first direction;
a plurality of nodules extending through the outer circumferential surface of the core via the plurality of nodule-forming portions; and
a filler connected to the plurality of nodules and filled in the injection line and the inflow portion.

12. The substrate cleaning apparatus according to claim 11, wherein the brush actuator is provided on a first side of the hollow portion, and
wherein the cleaning liquid supply is provided on a second side of the hollow portion.

13. The substrate cleaning apparatus according to claim 12, wherein the core further comprises:
a water supply portion provided between the injection line and the hollow portion in the radial direction, and
wherein the cleaning liquid supply is configured to supply the cleaning liquid into the hollow portion through the water supply portion to be delivered to the filler and the plurality of nodules.

14. A method of manufacturing a cleaning brush, comprising:
forming a hollow portion in a core;
forming a plurality of nodule-forming portions on an outer circumferential surface of the core;
forming an injection line around the hollow portion;
forming an inflow portion connecting the injection line and the plurality of nodule-forming portions;
providing a mold having a plurality of cavities corresponding to the plurality of nodule-forming portions on the outer circumferential surface of the core; and
injecting a filler material through the injection line.

15. The method of manufacturing a cleaning brush according to claim 14, further comprising forming a water supply portion provided between the hollow portion and the injection line.

16. The method of manufacturing a cleaning brush according to claim 14, wherein each of the plurality of nodule-forming portions comprises:
a center groove; and
a peripheral groove formed around the center groove,
wherein the center groove is formed by tap processing.

17. The method of manufacturing a cleaning brush according to claim 16, wherein forming the plurality of nodule-forming portions on the outer circumferential surface of the core comprises:
forming a fixing hole in the peripheral groove; and
forming a connection hole in the peripheral groove to form a channel to connect with the injection line.

18. The method of manufacturing a cleaning brush according to claim 16, wherein the inflow portion is formed in the center groove.

19. The method of manufacturing a cleaning brush according to claim 14, wherein the filler comprises polyvinyl alcohol (PVA).

20. The method of manufacturing a cleaning brush according to claim 14, further comprising removing the mold after injecting the filler through the injection line.
